(19) United States
(12) Patent Application Publication
(10) Pub. No.: US 2018/0173064 A1
(43) Pub. Date: Jun. 21, 2018

(54) ELECTRO-OPTICAL DEVICE AND ELECTRONIC APPARATUS

(71) Applicant: SEIKO EPSON CORPORATION, Tokyo (JP)

(72) Inventor: Mitsutaka OHORI, Shiojiri-shi (JP)

(73) Assignee: SEIKO EPSON CORPORATION, Tokyo (JP)

(21) Appl. No.: 15/830,861

(22) Filed: Dec. 4, 2017

(30) Foreign Application Priority Data
Dec. 21, 2016 (JP) 2016-247507

(51) Int. Cl. G02F 1/1362; G02F 1/1368; H01L 29/786; H01L 27/12

(52) U.S. Cl. CPC G02F 1/136209; G02F 1/1368; H01L 29/78633; H01L 29/78618; G02F 2001/13685; H01L 27/1222; G02F 2001/136218; G02F 2202/104; H01L 29/78675

(57) ABSTRACT

An electro-optical device includes a thin film transistor provided for each pixel and a light shielding film that shields at least one end portion of the semiconductor layer of the thin film transistor. The light shielding film is a source electrode and a drain electrode which are in contact with an end portions of a first source and drain region and a second source and drain region of the semiconductor layer and a side surfaces thereof, and the electrodes are in contact with an intermediate layer in a lower layer of the semiconductor layer.

### BACKGROUND

### 1. Technical Field

The present invention relates to an electro-optical device and an electronic apparatus including the eletro-optical device.

### 2. Related Art

An active drive type liquid crystal display device used as light modulation means of a projector which is a projection type display device is known as an electro-optical device. The active drive type liquid crystal display device includes a pixel electrode and a transistor which is a switching element of the pixel electrode for each pixel.

In the liquid crystal display device used as the light modulation means, there is a possibility that a light leakage current flows in a transistor due to light incident on a pixel and the operation is unstable, as compared with a direct viewing type liquid crystal display device to which intense light is incident from a light source, and thus, a light shielding structure is applied to the transistor.

For example, JP-A-2002-90721 discloses an electro-optical device which shields a corner portion of a pixel electrode by widening a planarly projected width of a light shielding film laminated between a transistor and a pixel electrode, near the transistor as the light shielding structure. In addition, an example in which the light shielding film is a capacitance line or a signal line is illustrated.

In addition, for example, JP-A-2008-96970 discloses an electro-optical device in which an insulating film with a light shielding property that covers at least a part of a semiconductor layer of a transistor in a planar view is laminated on a transistor. In addition, hafnium oxide, zirconium oxide, and the like are used as the insulating film with a light shielding property.

However, in JP-A-2002-90721, an example in which a capacitor line or a signal line is disposed as a light shielding film so as to overlap a transistor in a planar view is described, and light incident from an end portion of a semiconductor layer of the transistor may not be sufficiently shielded.

In addition, in JP-A-2008-96970, an example is described in which a surface of a transistor is covered with an insulating film with a light shielding property except for a source electrode and a drain electrode connected to a semiconductor layer of a transistor. However, it is assumed that the insulating film with a light shielding property may have lower transmissivity than a gate insulating film. However, transmissivity of visible light of hafnium oxide or zirconium oxide exemplified as the insulating film with a light shielding property is 70% to 80% and it is hard to say that the insulating film has a sufficient light shielding property.

That is, the light shielding structures disclosed in JP-A-2002-90721 and JP-A-2008-96970 have a problem that it is difficult to prevent a light leakage current caused by light incident from an end portion of a semiconductor layer of a transistor from being generated.

### SUMMARY

An advantage of some aspects of the invention is that the invention can be realized by the following aspects or application examples.

### Application Example 1

According to this application example 1, there is provided an electro-optical device including a thin film transistor that is provided for each pixel, and a light shielding film that shields at least one end portion of a semiconductor layer of the thin film transistor.

According to this application, it is possible to provide an electro-optical device including a thin film transistor in which light incident on at least one end portion of a semiconductor layer is shielded by a light shielding film, and thereby, a light leakage current generated by light incident from at least one end portion of the semiconductor layer can be prevented from being generated and a stable operation is performed for each pixel.

In the device, it is preferable that the light shielding film be an electrode in contact with at least one end portion of the first source and drain region and the second source and drain region and a side surface thereof in the semiconductor layer.

In the configuration, by using a light shielding film as an electrode in contact with at least one end portion of the first source and drain region and the second source and drain region of a semiconductor layer and a side surface of the end portion, that is, a source electrode or a drain electrode, it is possible to shield light incident on at least one end portion of the semiconductor layer without requiring a process of newly providing a light shielding film.

In the device, it is preferable that the semiconductor layer be provided on a substrate, an intermediate layer overlapping at least one end portion of the semiconductor layer in a planar view be provided between the substrate and the semiconductor layer, and the electrode and the intermediate layer be in contact with each other on the at least one end portion side.

In the configuration, when an electrode functioning as a light shielding film is formed, an intermediate layer can be used as an etching stopper. In other words, an electrode functioning as a light shielding film which shields light incident on at least one end portion of a semiconductor layer can be reliably formed.

In the device, it is preferable that the intermediate layer be formed of a light shielding member.

In the configuration, light incident on at least one end portion of a semiconductor layer from a substrate side can also be shielded by an intermediate layer. That is, the light incident on at least one end portion of the semiconductor layer can be more reliably shielded.

In the device, it is preferable that the semiconductor layer be formed of high-temperature polysilicon, and the intermediate layer be selected from among polysilicon, an alloy, and metal silicide.

In the configuration, even if a semiconductor layer formed of high-temperature polysilicon is provided after an intermediate layer is provided, it is possible to prevent the intermediate layer from being degenerated by heat.

In the device, it is preferable that the light shielding film include an electrode in contact with at least one end portion of a first source and drain region and a second source and drain region of the semiconductor layer, and a portion which is in contact with the electrode and faces a side surface of the at least one end portion, and the electrode be formed of a different material from a portion facing the side surface of the at least one end portion.

In the configuration, a range of selection of a member shielding a side surface of at least one end portion of a semiconductor layer is expanded, and thus, a process design is easily performed.

### Application Example 2

According to this application example 2, there is provided an electronic apparatus including the electro-optical device described in the above-described application example.

According to this application, an electro-optical device capable of obtaining a stable operation with respect to incident light is provided, and thus, it is possible to provide an electronic apparatus in which a stable display quality is realized.

### BRIEF DESCRIPTION OF THE DRAWINGS

The invention will be described with reference to the accompanying drawings, wherein like numbers reference like elements.

FIG. 1 is a schematic plan view illustrating a configuration of a liquid crystal device according to a first embodiment.

FIG. 2 is a schematic cross-sectional view taken along a line II-II of the liquid crystal device according to the first embodiment illustrated in FIG. 1.

FIG. 3 is an equivalent circuit diagram illustrating an electrical configuration of the liquid crystal device according to the first embodiment.

FIG. 4 is a schematic plan view illustrating arrangement of pixels according to the first embodiment.

FIG. 5 is a schematic sectional view illustrating a structure of the pixel according to the first embodiment.

FIG. 6 is a schematic plan view illustrating a disposition of TFTs and signal wires of the liquid crystal device according to the first embodiment.

FIG. 7 is a schematic cross-sectional view illustrating a light shielding structure of the TFT taken along a line VII-VII of FIG. 6.

FIG. 8 is a schematic cross-sectional view illustrating the light shielding structure of the TFT taken along a line VIII-VIII of FIG. 6.

FIG. 9 is a schematic plan view illustrating a disposition of TFTs and signal wires of a liquid crystal device according to a second embodiment.

FIG. 10 is a schematic cross-sectional view illustrating a light shielding structure of the TFT taken along a line X-X of FIG. 9.

FIG. 11 is a schematic view illustrating a configuration of a projection display device as an example of an electronic apparatus according to a third embodiment.

FIG. 12 is a schematic plan view illustrating a disposition of a TFT and a signal wire of a modification example.

### DESCRIPTION OF EXEMPLARY EMBODIMENTS

Hereinafter, embodiments that specify the invention will be described with reference to the accompanying drawings. The drawings which are used are illustrated in an appropriately expanded or contracted manner, such that portions to be described are in a recognizable state.

In the present embodiment, an active drive type liquid crystal device that includes a thin film transistor (referred to as TFT) for each pixel as an electro-optical device will be described as an example. The liquid crystal device can be appropriately used, for example, as optical modulation means (liquid crystal light valve) of a projection type display device (liquid crystal projector) to be described below.

### First Embodiment

### Electro-Optical Device

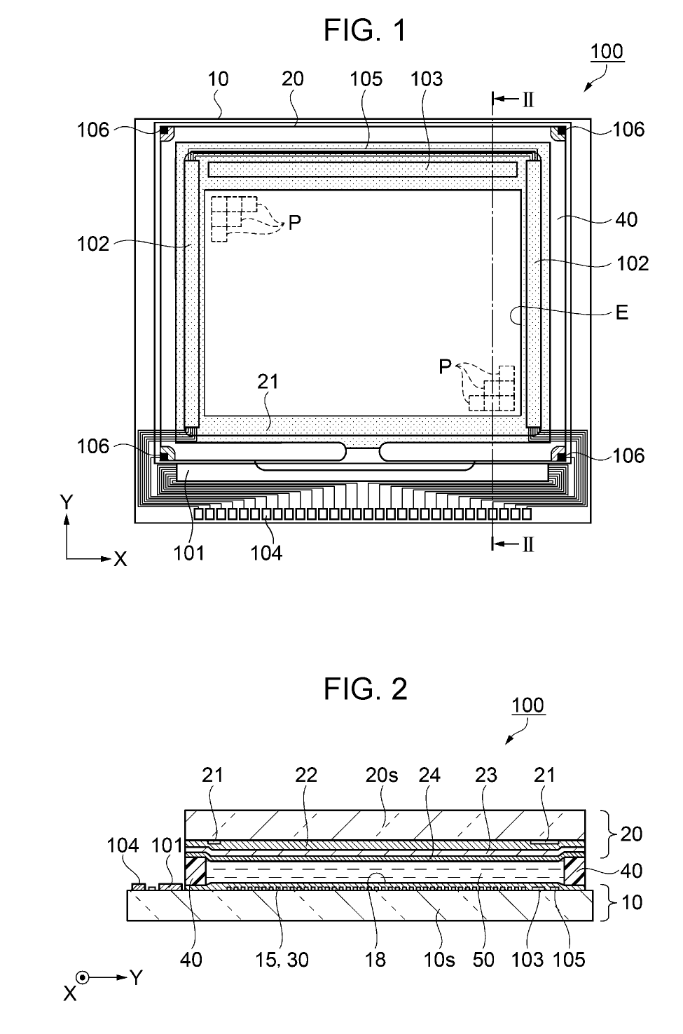

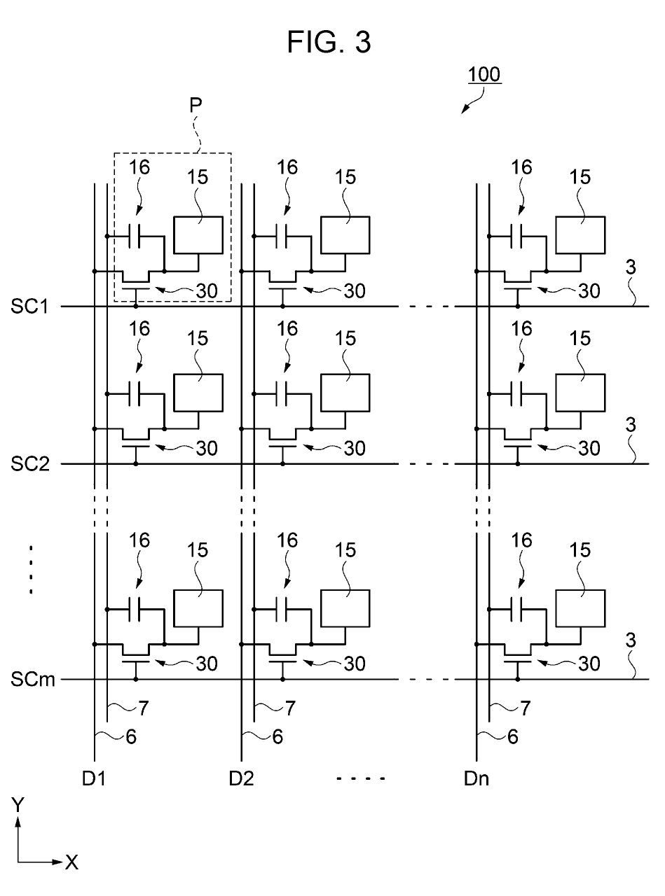

To begin with, a configuration of a liquid crystal device that is used as an electro-optical device according to the present embodiment will be described with reference to FIG. 1 to FIG. 3. FIG. 1 is a schematic plan view illustrating a configuration of the liquid crystal device. FIG. 2 is a schematic sectional view taken along the line II-II of the liquid crystal device illustrated in FIG. 1, and FIG. 3 is an equivalent circuit diagram illustrating an electrical configuration of the liquid crystal device.

As illustrated in FIG. 1 and FIG. 2, a liquid crystal device 100 according to the present embodiment includes an element substrate 10 and a counter substrate 20 that are disposed to face each other, and a liquid crystal layer 50 that is interposed between a pair of the substrates. A base member 10s of the element substrate 10 and a base member 20s of the counter substrate 20 use a light-transmittance material, such as a quartz substrate or a glass substrate. In the present specification, light transmittance means a property of capable of transmitting at least 85% or more of light in a visible light wavelength region. In addition, a light shielding property in the present specification means a property of shielding at least 95% or more of the light in the visible light wavelength region.

The element substrate 10 is slightly larger than the counter substrate 20. The element substrate 10 and the counter substrate 20 are bonded together via a sealing material 40 that is disposed in a frame shape along an outer edge of the counter substrate 20, and a liquid crystal layer 50 is configured by sealing liquid crystal having a positive or negative dielectric anisotropy in an interval therebetween. An adhesive such as a heat-curable or ultraviolet curable epoxy resin is employed in the sealing material 40. A spacer (not illustrated) for constantly maintaining the interval between a pair of substrates is mixed into the sealing material 40.

A display region E in which a plurality of pixels P are arranged in a matrix is provided in the inner side of the sealing material 40. In addition, in the counter substrate 20, a parting section 21 that surrounds the display region E is provided between the sealing material 40 and the display region E. The parting section 21 is configured with, for example, a metal with a light shielding property, a metal oxide, or the like. The display region E may include dummy pixels that are disposed to surround the plurality of pixels P, in addition to the plurality of pixels P contributing to displaying.

A terminal section in which a plurality of external connection terminals 104 are arranged is provided in the element substrate 10. A data line drive circuit 101 is provided between a first side portion along the terminal section of the element substrate 10 and the sealing material 40. In addition, a test circuit 103 is provided between the sealing material 40 along a second side portion facing the first side portion and the display region E. Furthermore, scan line drive circuits 102 are provided between the sealing material 40 along third and fourth side portions that are orthogonal to the first side portion and face each other and display region E. A plurality of wires 105 which connect the two scan line drive circuits 102 together are provided between the sealing material 40 of the second side portion and the test circuit 103.

The wires that are connected to the data line drive circuit 101 and the scan line drive circuit 102 are connected to a plurality of external connection terminals 104 that are arranged along the first side portion. Thereafter, it will be described that a direction along the first side portion is referred to as an X direction, and a direction along the third side portion and the fourth side portion is referred to as a Y direction. In the present specification, a direction orthogonal to the X direction and the Y direction, and a normal direction of the counter substrate 20 are referred to as a “planar view” or “planar”.

As illustrated in FIG. 2, the element substrate 10 includes the base member 10s, TFTs 30 or pixel electrodes 15 that are formed on a surface of the base member 10s on a liquid crystal layer 50 side, and an alignment film 18 that covers the pixel electrodes 15. The TFT 30 and the pixel electrode 15 are configuration elements of the pixel P. The pixel P will be described in detail below.

The counter substrate 20 includes the base member 20s, the parting sections 21 that are sequentially stacked on a surface of the base member 20s on the liquid crystal layer 50 side, a planarization layer 22, a common electrode 23, an alignment film 24, and the like.

As illustrated in FIG. 1, the parting sections 21 surround the display region E, and are provided in positions that respectively overlap the scan line drive circuit 102 and the test circuit 103 in a planar manner. Thereby, the parting section performs a function of shielding light incident on the peripheral circuit including the drive circuits from the counter substrate 20 side and preventing the peripheral circuit from malfunctioning due to the light. In addition, light is shielded such that unnecessary stray light is not incident on the display region E, and thus, it is possible to secure high contrast for displaying on the display region E.

The planarization layer 22 with light transparency is formed of, for example, an inorganic material such as a silicon oxide, and is provided to cover the parting sections 21. The planarization layer 22 is a silicon oxide film which is formed by using, for example, a plasma CVD method or the like, and has a thickness to the extent that roughness of a surface of the common electrode 23 which is formed on the planarization layer 22 can be reduced.

The common electrode 23 is formed of a transparent conductive film such as an indium tin oxide (ITO) or an indium zinc oxide (IZO), covers the planarization layer 22, and is electrically connected to wires on the element substrate 10 side by vertical connection sections 106 that are provided on four corners of the counter substrate 20, as illustrated in FIG. 1.

The alignment film 18 that covers the pixel electrodes 15 and the alignment film 24 that covers the common electrode 23 are set based on an optical design of the liquid crystal device 100, and employs an oblique deposition film (inorganic alignment film) of an inorganic material such as a silicon oxide. The alignment films 18 and 24 may employ an organic alignment film such as polyimide, in addition to the inorganic alignment film.

The liquid crystal device 100 is a transmission type, and employs an optical design of a normally white mode in which display is bright when the pixel P is not driven or a normally black mode in which display is dark when the pixel is not driven. Polarization elements are respectively disposed on an incident side and an exit side of light, according to an optical design.

Next, an electrical configuration of the liquid crystal device 100 will be described with reference to FIG. 3. The liquid crystal device 100 includes a plurality of scan lines 3 and a plurality of data lines 6 that are used as signal wires which are insulated with each other and orthogonal to each other in at least the display region E, and capacitance lines 7.

The pixel electrode 15, the TFT 30, and a retention capacitor 16 are provided in a region that is separated by the scan line 3 and the data line 6, and a pixel circuit of the pixel P is configured by those.

The scan line 3 is electrically connected to a gate of the TFT 30, the data line 6 is electrically connected to a source of the TFT 30, and the pixel electrode 15 is electrically connected to a drain of the TFT 30.

The data line 6 is connected to the data line drive circuit 101 (refer to FIG. 1). Image signals D1, D2, . . . , Dn are supplied to the respective pixels P from the data line drive circuit 101 through the data lines 6. The scan line 3 is connected to the scan line drive circuit 102 (refer to FIG. 1). Scan signals SC1, SC2, . . . , SCm are supplied to the respective pixels P from the scan line drive circuit 102 through the scan lines 3.

The image signals D1 to Dn which are supplied from the data line drive circuit 101 may be supplied to the data lines 6 in an ascending order of lines, and may be supplied to each group of a plurality of data lines 6 adjacent to each other. The scan line drive circuit 102 supplies the scan signals SC1 to SCm to the scan lines 3 in an ascending order of lines in a pulse manner at a predetermined timing.

The liquid crystal device 100 has a configuration in which the TFT 30 that is a switching element is in an ON state only for a predetermined period by inputting of the scan signals SC1 to SCm and thereby the image signals D1 to Dn that are supplied from the data lines 6 are written to the pixel electrodes 15 at a predetermined timing. The image signals D1 to Dn with predetermined levels that are written to the liquid crystal layer 50 through the pixel electrodes 15 are retained for a predetermined period between the common electrodes 23 and the pixel electrodes 15.

In order to prevent the retained image signals D1 to Dn from leaking, the retention capacitor 16 is connected in parallel to a liquid crystal capacitor formed between the pixel electrode 15 and the common electrode 23. The retention capacitor 16 is provided between the drain of the TFT 30 and the capacitance line 7.

The data lines 6 are connected to the test circuit 103 illustrated in FIG. 1, and the test circuit 103 is configured such that operation defects or the like of the liquid crystal device 100 can be confirmed by detecting the image signals during manufacturing of the liquid crystal device 100, but this is omitted in the equivalent circuit of FIG. 3.

In addition, the test circuit 103 may include a sampling circuit that samples the image signals and supplies the sampled image signals to the data lines 6, and a precharge circuit which supplies precharge signals with a predetermined voltage level to the data lines 6 prior to the image signals.

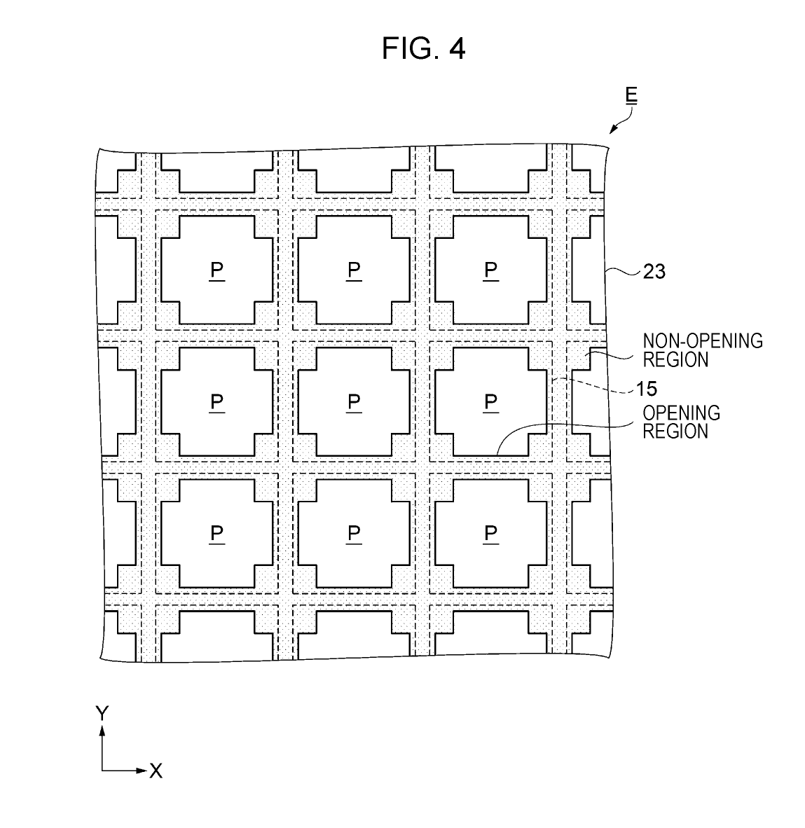

Next, a configuration of the pixel P in the liquid crystal device 100 will be described with reference to FIG. 4. FIG. 4 is a schematic plan view illustrating disposition of the pixels.

As illustrated in FIG. 4, the pixel P in the liquid crystal device 100 has, for example, an approximately rectangular (approximately square) opening region in a planar view. The opening region is surrounded by a non-opening region with a light shielding property that extends in the X and Y directions and is provided in a lattice pattern.

The scan line 3 illustrated in FIG. 3 is provided in the non-opening region which extends in the X direction. The scan line 3 uses a conductive member with a light shielding property, and a part of the non-opening region is configured by the scan line 3.

In the same manner, the data line 6 illustrated in FIG. 3 and the capacitance line 7 are provided in the non-opening region which extends in the Y direction. The data line 6 and the capacitance line 7 also use a conductive member with a light shielding property, and a part of the non-opening region is configured by the data line and the capacitance line.

The TFT 30 and the retention capacitor 16 which are illustrated in FIG. 3 are provided near an intersection of the non-opening regions. By providing the TFT 30 and the retention capacitor 16 near the intersection of the non-opening region with a light shielding property, a light leakage current of the TFT 30 is prevented from being generated and an aperture ratio of the opening region is secured. A detailed configuration of the pixel P will be described below, but a width of the non-opening region near the intersection is greater than widths of other portions, in relation to providing the TFT 30 and the retention capacitor 16 near the intersection.

The pixel electrode 15 is provided in each pixel P. The pixel electrode 15 is approximately a square in a planar view, and is provided in the opening region such that an outer edge of the pixel electrode 15 overlaps the non-opening region.

The liquid crystal device 100 according to the present embodiment is a transmission type, and the element substrate 10 adopts a light shielding structure which prevents light incident on the pixel P from being incident on the TFT 30, on the premise that light is incident from the counter substrate 20 side. Hereinafter, a structure of the element substrate 10 will be described.

### Structure of Element Substrate

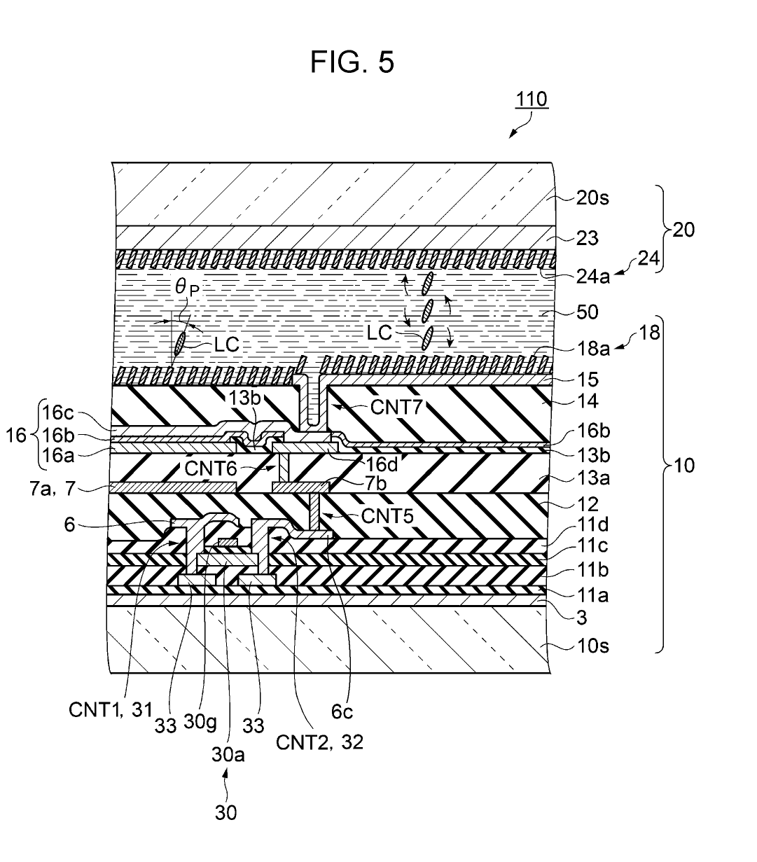

A structure of the pixel P in the liquid crystal device 100 and a structure of the element substrate 10 will be schematically described with reference to FIG. 5. FIG. 5 is a schematic sectional view illustrating the structure of the pixel.

As illustrated in FIG. 5, the scan line 3 is first formed on the base member 10s of the element substrate 10. The scan line 3 is formed of a simple metal including at least one of metals, for example, titanium (Ti), chromium (Cr), tungsten (W), tantalum (Ta), molybdenum (Mo), and the like, an alloy, metal silicide, poly silicide, nitride, or a material in which these are laminated, and has a light shielding property. The base member 10s according to the present embodiment is an example of a substrate according to the invention, and may be formed of, for example, a quartz substrate.

A first insulating film 11a is formed so as to cover the scan line 3, and an intermediate layer 33 is formed on the first insulating film 11a. The intermediate layer 33 is formed so as to overlap an end portion of a semiconductor layer 30a in a planar view with respect to the semiconductor layer 30a which will be formed later. The intermediate layer 33 is formed by applying the material used for the scan line 3, but it is preferable that a light shielding property be imparted to the intermediate layer 33.

A second insulating film 11b is formed so as to cover the intermediate layer 33, and the semiconductor layer 30a is formed on the second insulating film 11b in an island shape.

A third insulating film (gate insulating film) 11c is formed so as to cover the semiconductor layer 30a. Furthermore, a gate electrode 30g is formed at a position facing the semiconductor layer 30a having the third insulating film 11c interposed therebetween. The gate electrode 30g is formed using, for example, polysilicon with conductivity or the like.

A fourth insulating film 11d is formed so as to cover the gate electrode 30g and the third insulating film 11c, and two contact holes CNT1 and CNT2 passing through the second insulating film 11b, the third insulating film 11c, and the fourth insulating film 11d and reaching the intermediate layer 33 are formed at positions overlapping each end portion of the semiconductor layer 30a.

The first insulating film 11a, the second insulating film 11b, the third insulating film 11c, and the fourth insulating film 11d are formed of, for example, a silicon oxide and are formed by using, for example, a plasma CVD method with excellent coverage. When the contact holes CNT1 and CNT2 passing through the second insulating film 11b, the third insulating film 11c, and the fourth insulating film 11d are formed by, for example, dry etching, the intermediate layer 33 functions as an etching stopper.

Then, a conductive film is formed by using a conductive material with a light shielding property and low resistance such as aluminum (Al) or an alloy thereof so as to fill the two contact holes CNT1 and CNT2 and to cover the fourth insulating film 11d, patterning of the conductive film is performed, and thereby, the source electrode 31 and the data line 6 connected to the semiconductor layer 30a through the contact hole CNT1 are formed. At the same time, the drain electrode 32 (first relay electrode 6c) connected to the semiconductor layer 30a through the contact hole CNT2 is formed.

Next, the first interlayer insulating film 12 is formed so as to cover the data line 6, the first relay electrode 6c, and the fourth insulating film 11d. The first interlayer insulating film 12 is formed of, for example, a silicon oxide or nitride. Then, a planarization processing of planarizing unevenness of a surface caused by covering the region where the TFT 30 is provided is performed. For example, a chemical mechanical polishing processing (CMP processing), a spin coating processing or the like can be used as a method of the planarization processing.

A contact hole CNT5 passing through the first interlayer insulating film 12 is formed at a position overlapping the first relay electrode 6c. A conductive film formed of a metal with a light shielding property such as aluminum (Al), an alloy thereof or the like is formed so as to cover the contact hole CNT5 and cover the first interlayer insulating film 12. By patterning the conductive film, a wire 7a and a second relay electrode 7b electrically connected to the first relay electrode 6c through the contact hole CNT5 are formed. The wire 7a is formed so as to overlap the semiconductor layer 30a of the TFT 30 and the data line 6 in a planar view and functions as the capacitor line 7.

A second interlayer insulating film 13a is formed so as to cover the wire 7a and the second relay electrode 7b. The second interlayer insulating film 13a can also be formed by using, for example, a silicon oxide, nitride or oxynitride.

A contact hole CNT6 is formed at a position overlapping the second relay electrode 7b of the second interlayer insulating film 13a. A conductive film is formed of a metal with a light shielding property such as aluminum (Al), an alloy thereof or the like so as to cover the contact hole CNT 6 and cover the second interlayer insulating film 13a. By patterning the conductive film, a first capacitance electrode 16a and a third relay electrode 16d are formed.

An insulating protective film 13b is formed by patterning so as to cover an outer edge of the first capacitance electrode 16a which faces the second capacitance electrode 16c through the dielectric layer 16b which will be formed later. In addition, the protective film 13b is formed by patterning so as to cover an outer edge of the third relay electrode 16d except for a portion overlapping the contact hole CNT 5. In order to prevent the first capacitance electrode 16a and the second capacitance electrode 16c from being short-circuited by etching the dielectric layer 16b at the time of patterning the second capacitance electrode 16c, the protective film 13b is formed so as to cover an outer edge of the first capacitance electrode 16a.

The dielectric layer 16b is formed so as to cover the protective film 13b and the first capacitance electrode 16a. A single layer film such as a silicon nitride film, hafnium oxide (HfO₂), alumina (Al₂O₃), or tantalum oxide (Ta₂O₅), or a multilayer film in which at least two types of the single layer films are laminated may be used as the dielectric layer 16b. The dielectric layer 16b of a portion overlapping the third relay electrode 16d in a planar view is removed by etching or the like. A conductive film formed of, for example, titanium nitride (TiN) is formed so as to cover the dielectric layer 16b, and by patterning the conductive film, a second capacitance electrode 16c disposed at a position facing the first capacitance electrode 16a and connected to the third relay electrode 16d is formed. The retention capacitor 16 is formed by the dielectric layer 16b, and the first capacitance electrode 16a and the second capacitance electrode 16c which interposes the dielectric layer 16b therebetween and face each other.

Next, a third interlayer insulating film 14 covering the second capacitance electrode 16c and the dielectric layer 16b is formed. The third interlayer insulating film 14 is also formed of, for example, oxide or nitride of silicon, and is subjected to planarization processing such as CMP processing. A contact hole CNT7 passing through the third interlayer insulating film 14 is formed so as to reach a portion of the second capacitance electrode 16c in contact with the third relay electrode 16d.

A transparent conductive film (electrode film) such as ITO is formed so as to cover the contact hole CNT7 and cover the third interlayer insulating film 14. The transparent conductive film (electrode film) is patterned to form the pixel electrode 15 electrically connected to the second capacitance electrode 16c and the third relay electrode 16d through the contact hole CNT7.

The second capacitance electrode 16c is electrically connected to the drain electrode 32 of the TFT 30 through the third relay electrode 16d, the contact hole CNT6, the second relay electrode 7b, the contact hole CNT5, and the first relay electrode 6c, and is electrically connected to the pixel electrode 15 through the contact hole CNT7.

The first capacitance electrode 16a is connected to the wire 7a through a contact hole (not illustrated in FIG. 5) provided in the second interlayer insulating film 13a. As described above, the wire 7a is formed so as to extend over the plurality of pixels P, and functions as the capacitance line 7 of the equivalent circuit (see FIG. 3). A fixed potential is applied to the wiring 7a (capacitance line 7). Thereby, it possible to retain a potential applied to the pixel electrode 15 through the drain electrode 32 of the TFT 30 between the first capacitance electrode 16a and the second capacitance electrode 16c. The wiring structure of the element substrate 10 is not limited to this. For example, the first capacitance electrode 16a configuring the retention capacitor 16 may be disposed so as to function as the capacitance line 7.

An alignment film 18 is formed so as to cover the pixel electrode 15, and an alignment film 24 is formed so as to cover the common electrode 23 of the counter substrate 20 disposed at a position facing the element substrate 10 through the liquid crystal layer 50. The alignment films 18 and 24 are inorganic alignment films and are configured with groups of columns (columnar bodies) 18a and 24a in which inorganic materials such as silicon oxide are, for example, obliquely deposited from a predetermined direction and accumulated in a column shape. Liquid crystal molecules LC having negative dielectric anisotropy with respect to the alignment films 18 and 24 have a pretilt angle θp of 3 to 5 degrees in an inclination direction of the columns 18a and 24a with respect to a normal direction of an alignment film surface, and has approximately a vertical alignment (VA). By applying an AC voltage (drive signal) between the pixel electrode 15 and the common electrode 23 to drive the liquid crystal layer 50, the liquid crystal molecules LC behave to be inclined in a direction of the electric field generated between the pixel electrode 15 and the common electrode 23. Light Shielding Structure of TFT

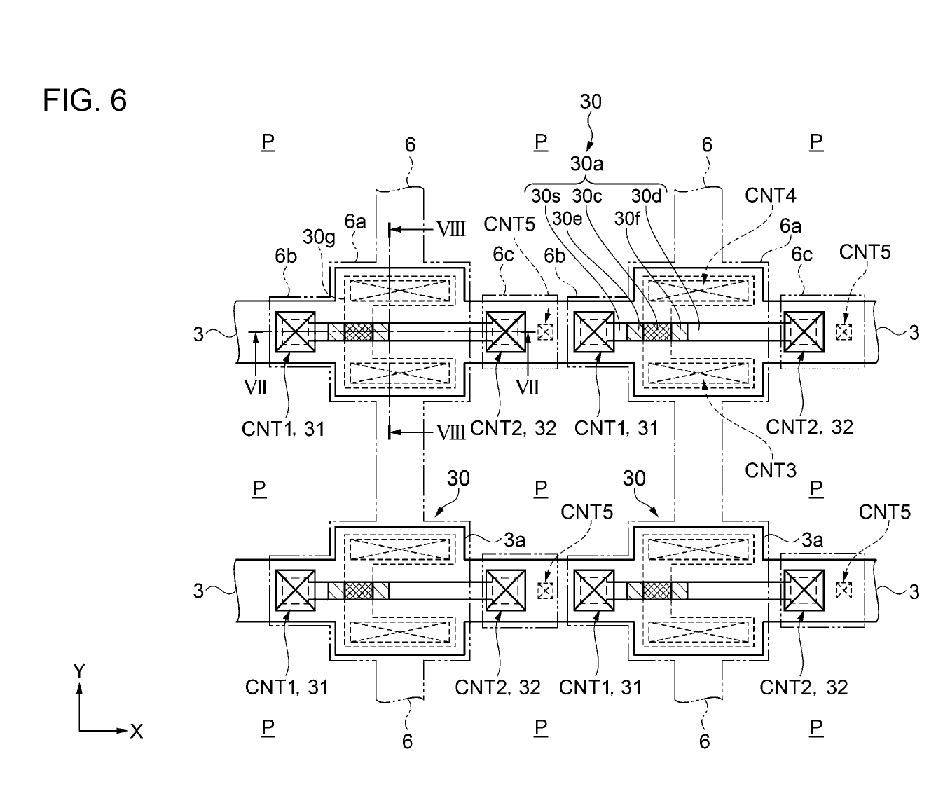

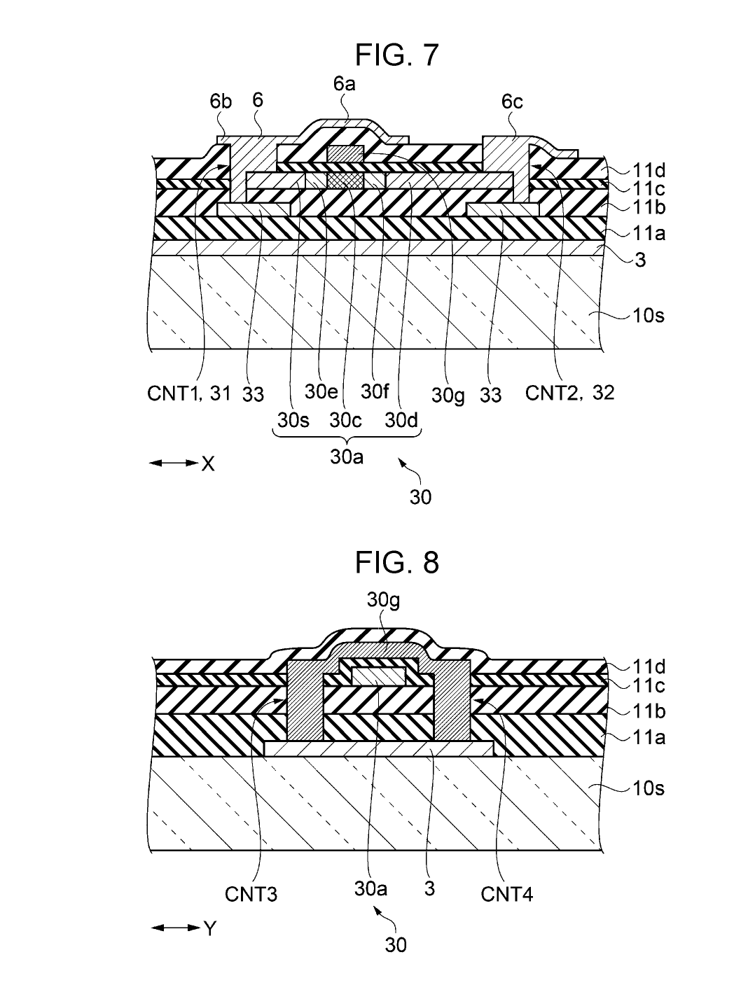

Next, a light shielding structure of the TFT 30 will be described with reference to FIGS. 6 to 8. FIG. 6 is a schematic plan view illustrating a disposition of TFTs and the signal wires, FIG. 7 is a schematic cross-sectional view illustrating the light shielding structure of the TFT taken along a line VII-VII of FIG. 6, and FIG. 8 is a schematic cross-sectional view illustrating the light shielding structure of the TFT taken along a line VIII-VIII of FIG. 6.

As illustrated in FIG. 6, the semiconductor layer 30a of the TFT 30 is disposed in the X direction along the scan line 3 at an intersection between the scan line 3 extending in the X direction and the data line 6 extending in the Y direction. The semiconductor layer 30a is formed of, for example, a polycrystalline silicon film, and is doped with impurity ions to form a lightly doped drain (LDD) structure including a first source and drain region 30s, a junction region 30e, a channel region 30c, a junction region 30f, and a second source and drain region 30d. The intersection between the scan line 3 and the data line 6 is expanded more than other portions in correspondence with the disposition of the TFT 30. Specifically, the scan line 3 has an extension portion 3a in which a main line portion extending in the X direction is expanded in the Y direction. The data line 6 has an extension portion 6a in which a main line portion extending in the Y direction is expanded in the X direction and a protrusion portion 6b protruding in the X direction from the extension portion 6a and overlapping the main line portion of the scan line 3. A portion where the extension portion 3a of the scan line 3 and the extension portion 6a of the data line 6 is the intersection, and a shape of the intersecting is a quadrangle in a planar view.

The first source and drain region 30s of the semiconductor layer 30a extends to the left side in the X direction from the intersection in the drawing, and is electrically connected to the protrusion portion 6b through the contact hole CNT1 at a position overlapping the protrusion portion 6b of the data line 6. That is, the contact hole CNT1 for connecting the first source and drain region 30s to the data line 6 functions as the source electrode 31.

In the drawing, the first relay electrode 6c is provided in an island shape at a position separated to the right side in the X direction from the extension portion 6a of the data line 6. The second source and drain region 30d of the semiconductor layer 30a extends to the right side in the X direction from the intersection and is electrically connected to the first relay electrode 6c through the contact hole CNT2 at a position overlapping the first relay electrode 6c. That is, the contact hole CNT2 for connecting the second source and drain region 30d to the first relay electrode 6c functions as the drain electrode 32. The contact hole CNT5 for connecting the first relay electrode 6c to the second relay electrode 7b is provided to the right more than the contact hole CNT2.

An end portion of the first source and drain region 30s and an end portion of the second source and drain region 30d are expanded in consideration of connection with the contact holes CNT1 and CNT2, respectively. In a planar view, the contact hole CNT 1 (source electrode 31) overlaps the end portion of the first source and drain region 30s and is formed to be slightly larger so as to protrude from the end portion. In the same manner, the contact hole CNT2 (drain electrode 32) overlaps the end portion of the second source and drain region 30d and is formed to be slightly larger so as to protrude from the end portion.

The gate electrode 30g of the TFT 30 is provided inside the intersection in a planar view and includes a portion extending in the X direction having the semiconductor layer 30a interposed therebetween and a portion which overlaps the channel region 30c, extends in the Y direction, and is connected to another portion extending in the X direction. Two contact holes CNT3 and CNT4 for being electrically connected to the scan line 3 are provided at a portion extending in the X direction of the gate electrode 30g.

In FIG. 6, a line VII-VII is a line that laterally cuts the semiconductor layer 30a in the X direction. As illustrated in FIG. 7, the source electrode 31 is formed integrally with the data line 6. The expansion portion 6a of the data line 6 is formed so as to overlap the first source and drain region 30s, the junction region 30e, the channel region 30c (gate electrode 30g), the junction region 30f, and a part of the second source and drain region 30d of the semiconductor layer 30a in a planar view (see FIG. 6). In addition, the source electrode 31 is in contact with the first source and drain region 30s and is in contact with the intermediate layer 33 provided at a lower layer by passing through the third insulating film (gate insulating film) 11c and the second insulating film 11b. The drain electrode 32 is formed integrally with the first relay electrode 6c. The drain electrode 32 is in contact with the second source and drain region 30d and is in contact with the intermediate layer 33 provided at a lower layer by passing through the third insulating film (gate insulating film) 11c and the second insulating film 11b.

It is preferable to form the intermediate layer 33 using the same material as the scan line 3, and can be formed of a simple metal including at least one of metals, for example, titanium (Ti), chromium (Cr), tungsten (W), tantalum (Ta), molybdenum (Mo), and the like, an alloy, metal silicide, poly silicide, nitride, or a material in which these are laminated, as described above, and has a light shielding property.

In the present embodiment, since the intermediate layer 33 is formed by using a conductive material, in order to prevent a short circuit between the source electrode 31 and the drain electrode 32, two intermediate layers 33 separated from each other are provided at positions overlapping the first source and drain region 30s and the second source and drain region 30d in a planar view. The intermediate layer 33 is not limited to being formed using the above-described material having conductivity, and may be formed by using a material that does not have conductivity as long as the material is not degenerated in high-temperature processing at the time of forming the semiconductor layer 30a.

In the present embodiment, the source electrode 31 and the drain electrode 32 correspond to the light shielding film according to the invention. That is, light incident on the end portion of the first source and drain region 30s is shielded by the source electrode 31 and the intermediate layer 33. In the same manner, light incident on the end portion of the second source and drain region 30d is shielded by the drain electrode 32 and the intermediate layer 33. In addition, most of the light incident directly on the semiconductor layer 30a is shielded by the extension portion 6a of the data line 6.

In FIG. 6, a line VIII-VIII is a line that laterally cuts the semiconductor layer 30a in the Y direction. As illustrated in FIG. 8, two contact holes CNT3 and CNT4 for connecting the gate electrode 30g to the scan line 3 are formed by passing through the third insulating film (gate insulating film) 11c, the second insulating film 11b, and the first insulating film 11a so as to interpose the semiconductor layer 30a in the Y direction. Therefore, light incident directly on the semiconductor layer 30a is shielded by the scan line 3. Most of light incident on the semiconductor layer 30a in the Y direction is shielded by the contact holes CNT3 and CNT4. That is, the semiconductor layer 30a of the TFT 30 shields light incident from above, below, the right, and the left, and light incident from the end portion of the semiconductor layer 30a extending in the X direction is also shielded.

According to the light shielding structure of the TFT 30 according to the present embodiment, not only the light incident from above, below, the right, and the left of the semiconductor layer 30a of the TFT 30 is shielded but also the light incident from the end portion of the semiconductor layer 30a extending in the X direction is shielded, and thus, it is difficult for a light leakage current generated by light incident on the pixel P to flow through the semiconductor layer 30a as compared with the light shielding structure of related art. Hence, it is possible to provide the liquid crystal device 100 that obtains a stable operation even if intense light is incident on the pixel P.

### Second Embodiment

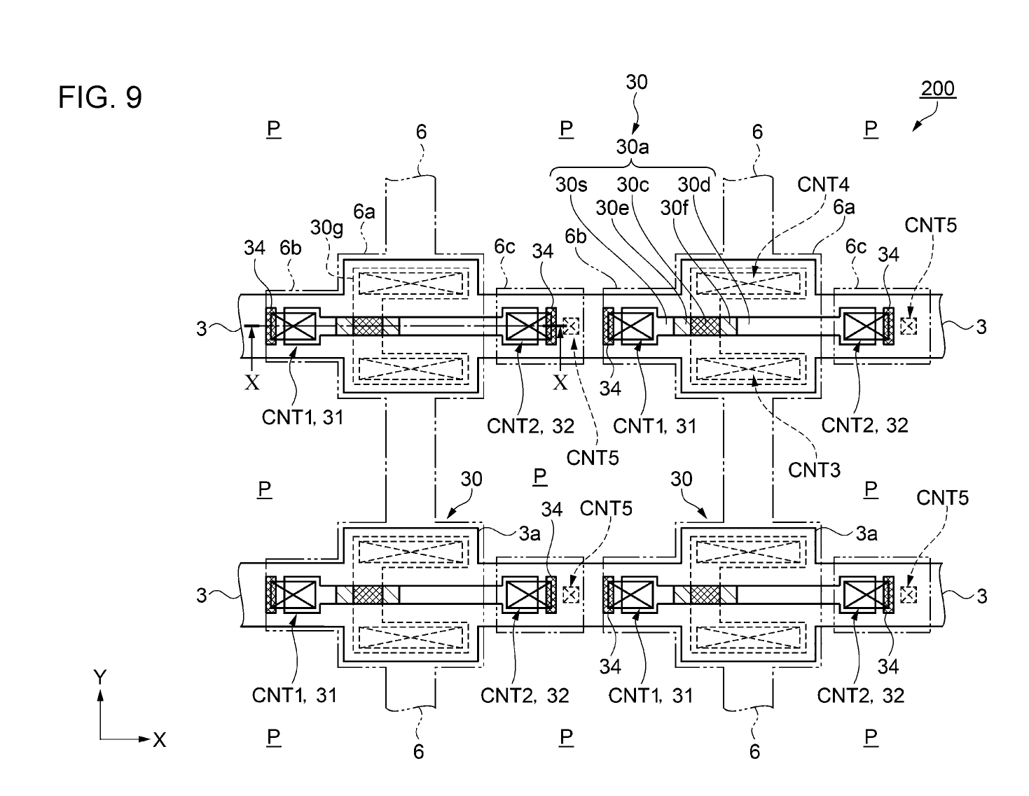

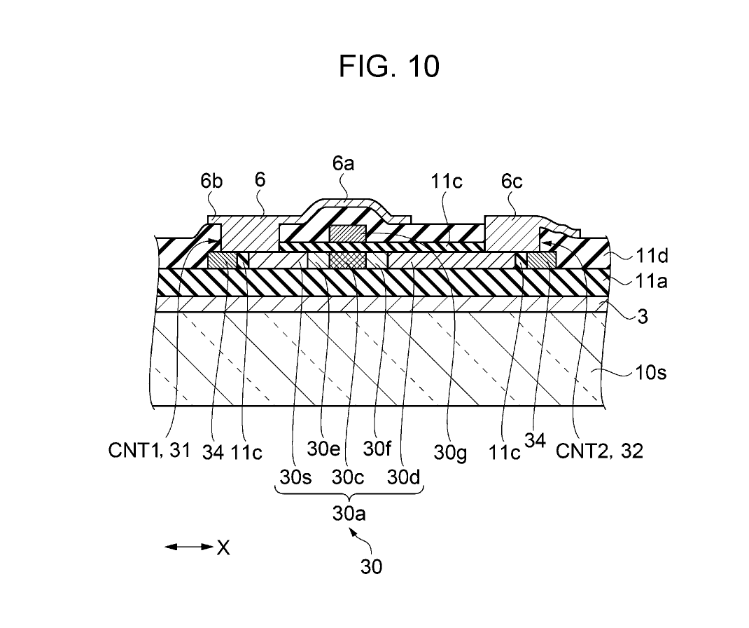

Next, a liquid crystal device according to a second embodiment will be described with reference to FIGS. 9 and 10. FIG. 9 is a schematic plan view illustrating a disposition of TFTs and signal wires in the liquid crystal device according to the second embodiment, and FIG. 10 is a schematic cross-sectional view illustrating a light shielding structure of the TFT taken along a line X-X of FIG. 9. The liquid crystal device according to the second embodiment is different from the liquid crystal device 100 according to the first embodiment in configurations of the contact holes CNT1 and CNT2 and a portion related thereto. Therefore, the same reference numerals or symbols are attached to the same configuration as the configuration of the liquid crystal device 100 according to the first embodiment, and detailed description thereof will be omitted.

As illustrated in FIG. 9, in the liquid crystal device 200 according to the present embodiment, the TFT 30 provided for each pixel P is provided at an intersection between the scan line 3 and the data line 6, and the semiconductor layer 30a having an LDD structure is disposed along the scan line 3.

A light shielding portion 34 of an island shape is provided on the left side in the X direction in a state of being separated from the end portion of the first source and drain region 30s of the semiconductor layer 30a. In the same manner, the light shielding portion 34 of an island shape is provided on the right side in the X direction in a state being separated from the end portion of the second source and drain region 30d of the semiconductor layer 30a. The light shielding portion 34 according to the present embodiment is an example as a portion facing a side surface of at least one end portion of the semiconductor layer according to the invention.

The contact hole CNT1 (source electrode 31) for connecting the first source and drain region 30s to the protrusion portion 6b of the data line 6 is provided to extend over the light shielding portion 34 from the extended end portion of the first source and drain region 30s in a planar view. In the same manner, the contact hole CNT2 (drain electrode 32) for connecting the second source and drain region 30d to the first relay electrode 6c is provided to extend over the light shielding portion 34 from the extended end portion of the second source and drain region 30d in a planar view.

In FIG. 9, the line X-X is a line that laterally cuts the semiconductor layer 30a in the X direction. As illustrated in FIG. 10, the scan line 3 is formed on the base member 10s, and the first insulating film 11a is formed so as to cover the scan line 3. The semiconductor layer 30a is formed of high-temperature polysilicon on the first insulating film 11a and has an LDD structure. The third insulating film (gate insulating film) 11c is formed so as to cover the semiconductor layer 30a. The gate electrode 30g is formed at a position facing the channel region 30c of the semiconductor layer 30a, on the third insulating film (gate insulating film) 11c. In addition, when the gate electrode 30g is formed, the light shielding portion 34 is formed on the end portion side of the first source and drain region 30s and on the end portion side of the second source and drain region 30d by using the same conductive material. One light shielding portion 34 is disposed so as to face the side surface of the end portion of the first source and drain region 30s through the third insulating film (gate insulating film) 11c, and the other light shielding portion 34 is disposed so as to face the side surface of the end portion of the second source and drain region 30d through the third insulating film (gate insulating film) 11c.

The fourth insulating film 11d is formed so as to cover the gate electrode 30g, the third insulating film 11c, the light shielding portion 34, and the first insulating film 11a. The contact hole CNT1 reaching the end portion of the first source and drain region 30s and the light shielding portion 34 by passing through the fourth insulating film 11d is formed. In addition, the contact hole CNT2 reaching the end portion of the second source and drain region 30d and the light shielding portion 34 by passing through the fourth insulating film 11d is formed. A conductive film such as aluminum which fills the contact holes CNT1 and CNT2 and covers the fourth insulating film 11d is formed, and by patterning the conductive film, the source electrode 31, the data line 6 (extension portion 6a and protrusion portion 6b), the drain electrode 32, and the first relay electrode 6c are formed.

In the present embodiment, the source electrode 31, the drain electrode 32, and the light shielding portion 34 correspond to the light shielding film according to the invention. The source electrode 31 and the drain electrode 32 are formed of a conductive material with low resistance such as aluminum, and the light shielding portion 34 is formed of the same material as the gate electrode 30g, for example, conductive polysilicon or the like. That is, the source electrode 31 and the drain electrode 32 are formed by using different materials from the light shielding portion 34, and both have a light shielding property.

According to the light shielding structure of the TFT 30 according to the present embodiment, most of light incident directly on the semiconductor layer 30a of the TFT 30 is shielded by the extension portion 6a of the data line 6. Light incident directly from below the semiconductor layer 30a of the TFT 30 is shielded by the scan line 3. Most of light incident from the left and right of the semiconductor layer 30a is shielded by the contact holes CNT3 and CNT4. Furthermore, light incident on the end portion of the semiconductor layer 30a is shielded by the source electrode 31, the drain electrode 32, and the light shielding portion 34. Therefore, according to the present embodiment, it is possible to provide the liquid crystal device 200 that includes the TFT 30 in which a light leakage current generated by light incident on the pixel P hardly flows and which obtains a stable operation state.

In addition, in the present embodiment, there is no need to form the intermediate layer 33 and the second insulating film 11b covering the intermediate layer 33 with respect to the liquid crystal device 100 according to the first embodiment, and thus, it is possible to simplify a structure of the element substrate while securing a light shielding state of the TFT 30.

In the second embodiment, the third insulating film 11c remains between the end portion of the semiconductor layer 30a and the light shielding portion 34, but the invention is not limited thereto. The third insulating film 11c does not remain between the end portion of the semiconductor layer 30a and the light shielding portion 34, and may be in contact with the end portion of the semiconductor layer 30a and the light shielding portion 34.

### Third Embodiment

### Electronic Apparatus

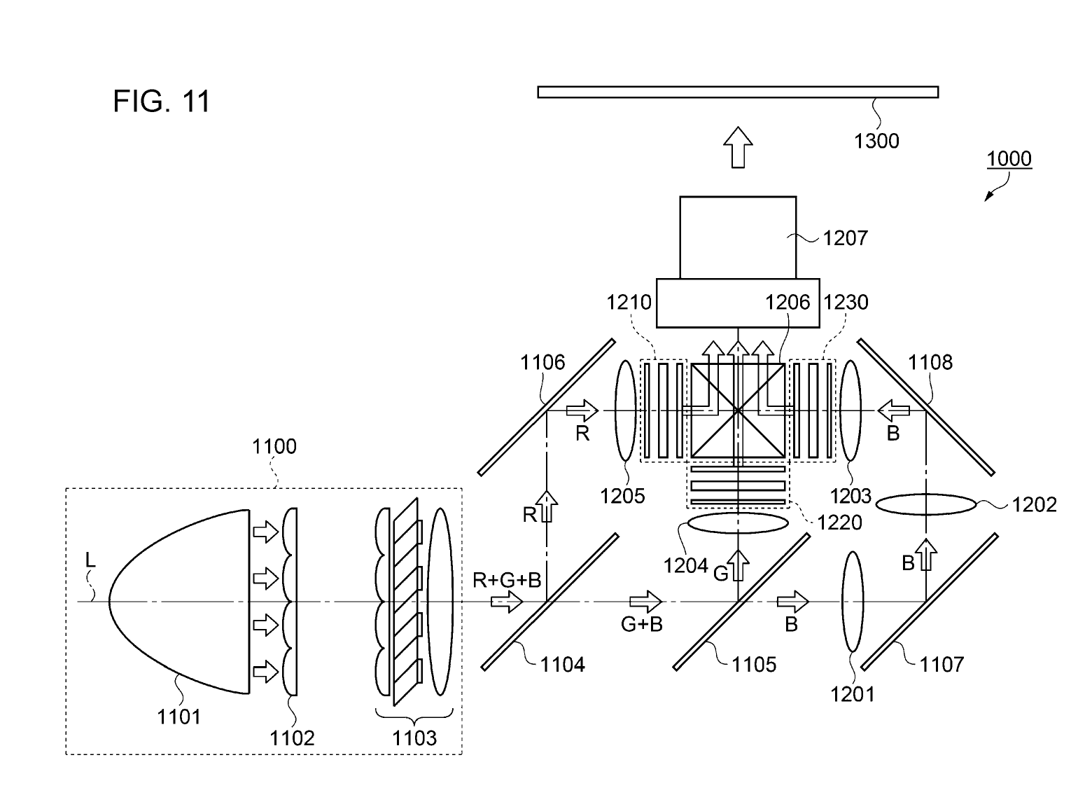

Next, a projection type display device will be described as an example with reference to FIG. 11 as an example of an electronic apparatus to which the liquid crystal device according to each of the above-described embodiment is applied. FIG. 11 is a schematic view illustrating a configuration of the projection type display device as the electronic apparatus.

As illustrated in FIG. 11, the projection type display device 1000 that is used as an electronic apparatus according to the present embodiment includes a polarized light illumination device 1100 disposed along a system optical axis L and two dichroic mirrors 1104 and 1105 that is used as light separating elements. In addition, three reflection mirrors 1106, 1107, and 1108, and five relay lenses 1201, 1202, 1203, 1204, and 1205 are included in the projection type display device. Furthermore, transmission type liquid crystal light valves 1210, 1220, and 1230 that are used as three optical modulation units, a cross dichroic prism 1206 that is used as a photosynthesis element, and a projection lens 1207 are included in the projection type display device.

The polarized light illumination device 1100 is schematically configured by, for example, a lamp unit 1101 that is used as a light source configured with a white light source such as an ultrahigh pressure mercury lamp or halogen lamp, an integrator lens 1102, and a polarized light conversion element 1103.

The dichroic mirror 1104 reflects red light (R) and makes green light (G) and blue light (B) pass through, among polarized light flux that is emitted from the polarized light illumination device 1100. The other dichroic mirror 1105 reflects the green light (G) that passes through the dichroic mirror 1104, and makes the blue light (B) pass through.

The red light (R) that is reflected by the dichroic mirror 1104 is reflected by the reflection mirror 1106, and thereafter, is incident on the liquid crystal light valve 1210 through the relay lens 1205.

The green light (G) that is reflected by the dichroic mirror 1105 is incident on the liquid crystal light valve 1220 through the relay lens 1204.

The blue light (B) that passes through the dichroic mirror 1105 is incident on the liquid crystal light valve 1230 through a light guide system configured with the three relay lenses 1201, 1202, and 1203, and the two reflection mirrors 1107 and 1108.

The liquid crystal light valves 1210, 1220, and 1230 are respectively disposed to face the incident surfaces of each color light of the cross dichroic prism 1206. The colored light incident on the liquid crystal light valves 1210, 1220, and 1230 is modulated based on video information (video signal) and is emitted toward the cross dichroic prism 1206. The prism is configured with four rectangular prisms bonded to each other, and a dielectric multilayer that reflects red light and a dielectric multilayer that reflects blue light are formed in a cross shape in the inner surface of the prism. Three colored lights are synthesized by the dielectric multilayers, and lights that represent color images are synthesized. The synthesized light is projected onto a screen 1300 by the projection lens 1207 that is a projection optical system, and an image is enlarged to be displayed.

The liquid crystal light valve 1210 is a device in which the liquid crystal device 100 (refer to FIG. 1) according to the first embodiment is employed. A pair of polarization elements disposed in the cross Nicol are disposed with a gap on the incident side and the emission side of the color light of the liquid crystal device 100. The other liquid crystal light valves 1220 and 1230 are the same as the liquid crystal light valve 1210.

According to the projection type display device 1000, the liquid crystal device 100 according to the first embodiment is used as the liquid crystal light valves 1210, 1220, and 1230, and thus, it is possible to project bright display, to prevent light leakage current of the TFT 30 from being generated, and to provide the projection type display device 1000 which obtains a stable drive state. Even if the liquid crystal device 200 according to the second embodiment is employed as the liquid crystal light valves 1210, 1220, and 1230, the same effects are obtained.

The invention is not limited to the above-described embodiments, and can be appropriately changed within a range without departing from the gist or idea of the invention which are read from the claims and the entire specification, and an electro-optical device according to the change and an electronic apparatus to which the electro-optical device is applied are also included in the technical scope of the invention. Various modification examples other than the above-described embodiments are conceivable. Hereinafter, the modification example will be described.

### Modification Example 1

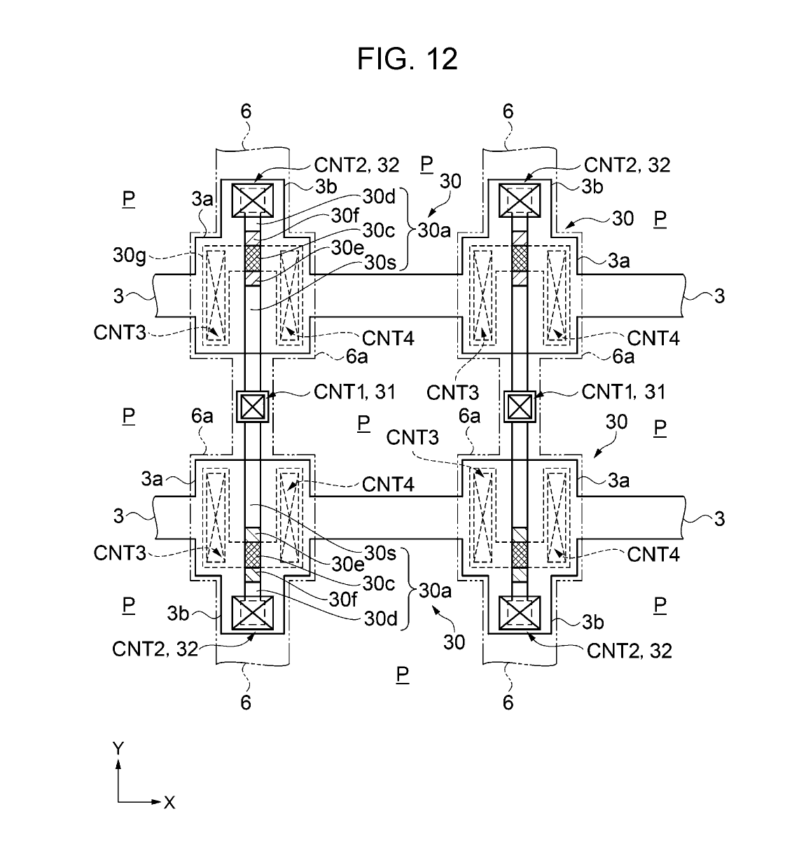

In the liquid crystal devices 100 and 200 according to the above-described embodiments, the semiconductor layer 30a of the TFT 30 is not limited to being disposed along the scan line 3 in the X direction. FIG. 12 is a schematic plan view illustrating a disposition of the TFTs and the signal wires according to the modification example. As illustrated in FIG. 12, the TFT 30 according to the modified example is disposed in the Y direction along the data line 6 at the intersection of the scan line 3 and the data line 6. In addition, the two TFTs 30 of the pixels P adjacent to each other in the Y direction share the contact hole CNT1 (source electrode 31), and the first source and drain regions 30s are connected to each other in the two semiconductor layers 30a.

The contact holes CNT2 (drain electrodes 32) are provided at both ends of the two semiconductor layers 30a connected to each other in the Y direction. The contact hole CNT2 (drain electrode 32) is formed slightly larger than the enlarged end portion of the second source and drain region 30d, and is connected to the intermediate layer 33 provided at a lower layer of the semiconductor layer 30a in the same manner as the liquid crystal device 100 according to the first embodiment, while not illustrated in FIG. 12. That is, there is provided a configuration in which light incident on the end portion of the second source and drain region 30d is shielded by the drain electrode 32 and the intermediate layer 33. In this case, the intermediate layer 33 provided at positions overlapping both ends of the two semiconductor layers 30a connected to each other in the Y direction may not be required to electrically isolate, and may be disposed so as to overlap the two semiconductor layers 30a in a planar view.

The scan line 3 includes the extension portion 3a expanded at the intersection with the data line 6, and the protrusion portion 3b protruding from the extension portion 3a in the Y direction and overlapping the contact hole CNT2 (drain electrode 32) in a planar view.

The gate electrode 30g has a portion that overlaps the channel region 30c of the semiconductor layer 30a in a planar view and extends in the X direction, and a portion that includes the semiconductor layer 30a interposed therebetween and extends in the Y direction. The two contact holes CNT3 and CNT4 are provided for electrically connecting the scan line 3 to a portion of the gate electrode 30g extending in the Y direction.

According to the disposition of the TFT 30 according to the modification example, the light incident directly on the semiconductor layer 30a from above is shielded by the data line 6 and the extension portion 6a. In addition, most of the light incident directly on the semiconductor layer 30a from below is shielded by the scan line 3. Furthermore, light incident on the end portion of the second source and drain region 30d of the semiconductor layer 30a is shielded by the drain electrode 32 and the intermediate layer 33. In the modification example, there is provided a configuration in which malfunction of the TFT 30 due to generation of a light leakage current on the second source and drain region 30d side affecting a potential applied to the pixel electrode 15 in particular is suppressed. As such, the light shielding film and the intermediate layer 33 for suppressing the generation of the light leakage current may be disposed so as to correspond to one end portion of both ends of the semiconductor layer 30a.

### Modification Example 2

In each of the embodiments described above, the intermediate layer 33 disposed so as to overlap the end portion of the semiconductor layer 30a in a planar view is formed by using a light shielding member, but the invention is not limited thereto. If the contact hole CNT1 (source electrode 31) and the contact hole CNT2 (drain electrode 32) as a light shielding film shielding the end portion of the semiconductor layer 30a are formed to function as etching stoppers, the intermediate layer 33 may be formed by using, for example, a light-transmittance member such as silicon nitride (SiN) or polysilicon.

### Modification Example 3

An electro-optical device to which the light shielding structure of the TFT 30 according to each of the above-described embodiments is applied is not limited to the transmission type liquid crystal device 100 (or the liquid crystal device 200), and can also be applied to a reflection type liquid crystal device. In addition, the electro-optical device is not limited to a liquid crystal device, and may be applied to a transistor which includes a light emitting element such as an organic EL element for each pixel and controls switching of light emission of the light-emitting element.

### Modification Example 4

An electronic apparatus to which the liquid crystal device according to each of the above-described embodiments is applied are not limited to the projection type display device 1000 according to the third embodiment. For example, the counter substrate 20 of the liquid crystal device 100 may have color filters corresponding to at least red (R), green (G), and blue (B), and a projection display device may have a single plate configuration. In addition, the liquid crystal device according to each of the above-described embodiments can be suitably used as a display portion of an information terminal apparatus such as a projection type head up display (HUD), a head mounted display (HMD), an electronic book, a personal computer, a digital still camera, a liquid crystal television, a view finder type or monitor direct view type video recorder, a car navigation system, an electronic diary, a POS, or the like.

The entire disclosure of Japanese Patent Application No. 2016-247507, filed Dec. 21, 2016 is expressly incorporated by reference herein.

What is claimed is:

1. An electro-optical device comprising:
a thin film transistor that is provided for each pixel; and
a light shielding film that shields at least one end portion of a semiconductor layer of the thin film transistor.

2. The electro-optical device according to claim 1, wherein the light shielding film is an electrode in contact with at least one end portion of the first source and drain region and the second source and drain region and a side surface thereof in the semiconductor layer.

3. The electro-optical device according to claim 2,
wherein the semiconductor layer is provided on a substrate,
wherein an intermediate layer overlapping at least one end portion of the semiconductor layer in a planar view is provided between the substrate and the semiconductor layer, and
wherein the electrode and the intermediate layer are in contact with each other on the at least one end portion side.

4. The electro-optical device according to claim 3, wherein the intermediate layer is formed of a light shielding member.

5. The electro-optical device according to claim 3,
wherein the semiconductor layer is formed of high-temperature polysilicon, and
wherein the intermediate layer is selected from among polysilicon, an alloy, and metal silicide.

6. The electro-optical device according to claim 1,
wherein the light shielding film includes an electrode in contact with at least one end portion of a first source and drain region and a second source and drain region of the semiconductor layer, and a portion which is in contact with the electrode and faces a side surface of at least one end portion, and
wherein the electrode is formed of a different material from a portion facing the side surface of the at least one end portion.

7. An electronic apparatus comprising:
the electro-optical device according to claim 1.

8. An electronic apparatus comprising:
the electro-optical device according to claim 2.

9. An electronic apparatus comprising:
the electro-optical device according to claim 3.

10. An electronic apparatus comprising:
the electro-optical device according to claim 4.

11. An electronic apparatus comprising:
the electro-optical device according to claim 5.

12. An electronic apparatus comprising:
the electro-optical device according to claim 6.
